(19) United States
(12) Patent Application Publication
(10) Pub. No.: US 2009/0256221 A1
(43) Pub. Date: Oct. 15, 2009

(54) METHOD FOR MAKING VERY SMALL ISOLATED DOTS ON SUBSTRATES

(76) Inventors: Len Mei, San Jose, CA (US); Yue-Song He, San Jose, CA (US)

Correspondence Address: Haynes and Boone, LLP;IP Section, 2323 Victory Avenue, SUITE 700, Dallas, TX, 75219, US

(21) Appl. No.: 12/101,908

(22) Filed: Apr. 11, 2008

(51) Int. Cl. H01L 29/82; H01L 21/306

(52) U.S. Cl. 257/421; 438/3; 257/E21.215; 257/E29.323

(57) ABSTRACT

A method for forming very small isolated dots of a target material, e.g., a ferromagnetic material or phase change material, on a substrate includes providing a substrate having a layer of the target material disposed on a surface thereof, etching the layer of target material so as to form a plurality of lines of the material on the surface of the substrate, and etching the lines of the target material so as to form a rectangular matrix of substantially similar, very small isolated dots of the target material on the substrate. By the successive formation of orthogonally intersecting linear patterns on the substrate, including the formation and use of “hard” etch masks, spacer approach and selective etching techniques, the method enables very small (<65 nm) isolated dots of the target material to be formed on the substrate reliably and with the use of conventional 193 nm wavelength photolithographic methods and apparatus.

### BACKGROUND

This disclosure relates to semiconductor manufacturing methods in general, and in particular, to a photolithographic method for making very small isolated dots of a target material on a substrate.

In the manufacture of a variety of semiconductor products, there is often a need to print very small, isolated areas, or “dots,” of a target material on a substrate, for example, in the manufacture of Magnetoresistive Random Access Memory (MRAM) or Phase Change Memory (PCM). MRAM and PCM are non-volatile types of memory devices useful for data storage in digital computers. Unlike conventional CMOS RAM chip technologies, MRAM does not store data in the form of different transistor threshold voltage states, but rather, by magnetic storage elements in the form of memory cells containing very fine dots of a ferromagnetic material formed on a semiconductor substrate and capable of accepting a magnetic “charge”. In general, it is desirable that the magnetic dots be formed as small as reliably possible so that the amount of power required to write data to the cells is correspondingly small and so that the density of the cells that can be reliably formed in a given area on the substrate is correspondingly high.

However, it is very difficult to print small, i.e., less than 65 nanometers (nm) isolated dot geometries using conventional 193 nm wavelength photolithography tools. The conventional methods typically include using a positive photoresist to pattern the isolated structure prior to etching. Alternatively, Optical Proximity Correction (OPC) techniques may be used. Regardless, however, because of light interference problems, the relatively small photoresist structures used to form the dots can easily be overexposed and then washed out during development, resulting in the formation of defective dot geometries.

Accordingly, a need exists in the semiconductor manufacturing field for a photolithography process that overcomes the problem of isolated small pattern washout during development of the conventional photolithographic processes.

### SUMMARY

In accordance with the present disclosure, a simple yet reliable method is provided for forming very fine (<65 nm) isolated target material dots on a semiconductor substrate using conventional photolithographic methods and apparatus, thereby overcoming the above and other problems of the prior art, and enabling high reliability, low cost memory products to be produced.

In one exemplary embodiment, the method comprises: providing a substrate having a layer of the target material disposed on a surface thereof; etching the layer of target material so as to form a plurality of lines thereof on the surface of the substrate; and, etching the lines of the target material so as to form a rectangular matrix of substantially similar, very small isolated dots of the target material on the surface of the substrate. The etching of the layer of target material may comprise forming a plurality of linear spacers of a hard etch masking material on a surface of the layer of target material, selectively etching the layer of target material using the linear spacers as an etch mask so as to remove all of the target material from the substrate except for that underlying the spacers; and, removing the linear spacers from the substrate. The etching of the lines of target material may comprise forming a plurality of lines of a photoresist material on the surface of the substrate, the photoresist lines extending in a direction generally perpendicular to the lines of the target material, selectively etching the lines of target material using the photoresist lines as an etch mask so as to remove all of the target material from the substrate except for that underlying the photoresist lines, and removing the photoresist lines from the substrate.

A better understanding of the above and many other features and advantages of the novel photolithography method of the present disclosure may be obtained from a consideration of the detailed description of an exemplary embodiment thereof below, particular if such consideration is made in conjunction with the appended drawings described below, wherein like reference numbers are used to refer to like elements in the respective figures thereof.

### BRIEF DESCRIPTION OF THE DRAWINGS

FIG. 1 is a partial cross-sectional view of a substrate, showing in an intermediate processing stage of an exemplary embodiment of a method for forming very fine geometry isolated magnetic dots of a target material thereon in accordance with the present disclosure;

FIG. 2 is a partial cross-sectional view through the substrate of FIG. 1, showing a subsequent processing stage of the exemplary method;

FIG. 3 is a partial cross-sectional view through the substrate of FIG. 2, showing a subsequent processing stage of the method;

FIG. 4 is partial top plan view of the substrate of FIG. 3, showing a subsequent processing stage of the method;

FIG. 5 is an enlarged partial cross-sectional view of the substrate of FIG. 4, as seen along the lines of the section 4-4 taken therein, and showing a subsequent processing stage of the method;

FIG. 6 is a partial cross-sectional view through the substrate of FIG. 5, showing a subsequent processing stage of the method;

FIG. 7 is a partial top plan view of the substrate of FIG. 6, showing a subsequent processing stage of the method;

FIG. 8 is a partial cross-sectional view of the substrate of FIG. 7, as seen along the lines of the section 8-8 taken therein, and showing a subsequent processing stage of the method;

FIG. 9 is an enlarged partial cross-sectional view of the substrate of FIG. 7, as seen along the lines of the section 9-9 taken therein, and showing a subsequent processing stage of the method;

FIG. 10 is a partial cross-sectional view of the substrate of FIG. 9, showing a subsequent processing stage of the method;

FIG. 11 is a partial top plan view of the substrate of FIG. 10, showing a subsequent processing stage of the method;

FIG. 12 is a partial cross-sectional view of the substrate of FIG. 11, showing a subsequent processing stage of the method;

FIG. 13 is a partial top plan view of the substrate of FIG. 6, showing a subsequent processing stage of an alternative embodiment of the method;

FIG. 14 is a partial cross-sectional view of the substrate of FIG. 13, as seen along the lines of the section 14-14 taken therein, and showing a subsequent processing stage of the alternative method;

FIG. 15 is an enlarged partial cross-sectional view of the substrate of FIG. 13, as seen along the lines of the section 15-15 taken therein, and showing a subsequent processing stage of the alternative method;

FIG. 16 is a partial cross-sectional view of the substrate of FIG. 15, showing a subsequent processing stage of the alternative method;

FIG. 17 is a partial top plan view of the substrate of FIG. 17, showing a subsequent processing stage of the alternative method; and,

FIG. 12 is a partial cross-sectional view of the substrate of FIG. 17, showing a subsequent processing stage of the alternative method.

### DETAILED DESCRIPTION

In accordance with the present disclosure, a method is provided for reliably forming very fine (<65 nm) isolated dots of a target material, e.g., a ferromagnetic material, on a substrate, e.g., a semiconductor substrate, using conventional photolithographic methods and apparatus. In comparison with conventional photoresist-to-pattern processes, the novel method enables the printing of very small isolated dots of the target material without suffering pattern washout during the development step. In one exemplary embodiment, the novel method may comprise: (1) using an oxide spacer as a hard mask to etch the target material to form a plurality of very narrow first lines on the substrate; (2) removing the hard mask spacer; (3) using a photo mask to print second photoresist lines on the substrate that are perpendicular to the first lines; and, (4) performing a metal etch, thereby forming a rectangular matrix of isolated fine dots of the target material.

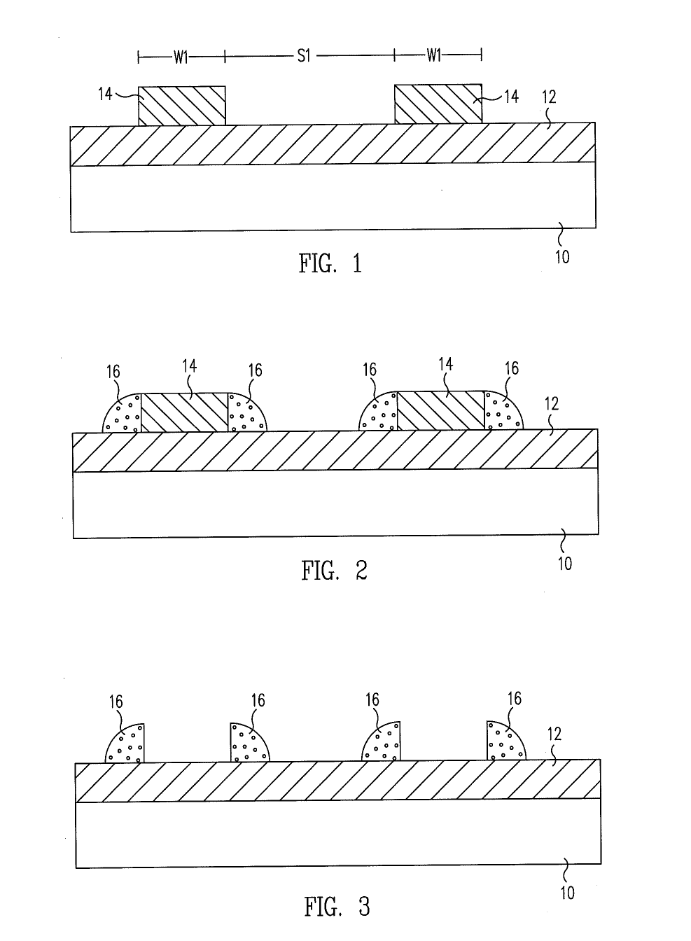

FIG. 1 is a partial cross-sectional view of a substrate 10, shown in an intermediate processing stage of the exemplary method. The substrate may comprise a semiconductor wafer, for example, a silicon (Si) or gallium arsenide (GaAs) wafer, and may include an upper, “active” surface within which electronic components (not illustrated), e.g., MRAM components, such as complementary metal oxide semiconductor (CMOS) transistors, have previously been formed using known semiconductor component fabrication techniques. The substrate 10 includes a layer of target material, e.g., a ferromagnetic metal 12 disposed on the upper surface thereof, and within which a pattern of very fine isolated dots of ferromagnetic material is to be formed on the substrate. The layer of magnetic material may be deposited on the substrate by a variety of processes, including chemical vapor deposition (CVD) processes.

With reference to FIG. 1, the exemplary method begins with the deposition of a layer of silicon nitride (Si₃N₄, or more generally, SiₓN_{y}) over the magnetic material layer 12, which may be effected by, e.g., a CVD process, followed by the deposition of a layer of photoresist (not illustrated) over the SiₓN_{y} layer, which may be effected by, e.g., a spin-coating process. The SiₓN_{y} layer may be deposited to a uniform thickness of, for example, about 1000 Å, or alternatively, may be deposited with a varying thickness, depending on the particular application at hand.

The photoresist (not illustrated) covering the SiₓN_{y} layer is then exposed to light through a mask (not illustrated) and developed to form a patterned etch mask comprising a plurality of parallel bars or stripes on the magnetic material layer 12, each having a width W1, and which are spaced apart from each other at a spacing S1. If a final target dot lateral width of x is assumed, then the photoresist lines are formed with respective widths W1 of about 3x. For instance, if the final dot width is targeted to be 30 nm, the stripes are each formed with a lateral width W1 about 90 nm. These can be printed out using a conventional 193 nm wavelength photo tool. On other hand, it is difficult to use conventional photo resist to definite a 30 nm line without overexposure and pattern lifting after development thereof. For reasons that will become clear below, the pitch or spacing S1 of the photoresist lines is set at about 150 nm.

The substrate 10 is then etched, preferably with an anisotropic etching process, such as a reactive ion or plasma etching process, using the patterned photoresist as an etching mask, down to the upper surface of the magnetic material layer 12. The photoresist etch mask is then stripped away, e.g., with a wet or dry stripping process, e.g., an acid bath or ashing process, resulting in the structure illustrated in FIG. 1, comprising a plurality of parallel SiₓN_{y} lines 14 corresponding to the photoresist lines and extending over the upper surface of the layer of magnetic material 12 on the substrate 10, each having a width W1 of about 90 nm and disposed at a pitch or spacing S1.

In the next stage of the exemplary method, rounded linear oxide “spacers” 16 are created on the substrate 10. As illustrated in FIGS. 2 and 3, this is effected by first depositing a conformal layer of silicon oxide (SiO₂, or more generally SiₓO_{y}) over the entire substrate structure of FIG. 1 to a suitable thickness, e.g., 1000 Å, then etching the SiₓO_{y} layer with an anisotropic, vertical blanket etching process selective to silicon nitride and the magnetic material 12, down to the upper surface of the layer of magnetic material 12, thereby removing almost all of the SiₓO_{y} layer, except for characteristically rounded SiₓO_{y} spacers 16 disposed on the sidewalls of each SiₓN_{y} line 14, as illustrated in FIG. 2. An exemplary lateral width of each SiₓO_{y} spacer 16 is about 30 nm. The structure of FIG. 2 is then subjected to a second blanket etching process, one which is selective to both the magnetic material 12 and the SiₓO_{y} lines 16, so as to remove the SiₓN_{y} lines 14 from between the SiₓO_{y} spacers 16, resulting in the structure illustrated in FIG. 3, comprising a plurality of parallel, linear SiₓO_{y} spacers extending over the upper surface of the layer of magnetic material 12 on the substrate 10.

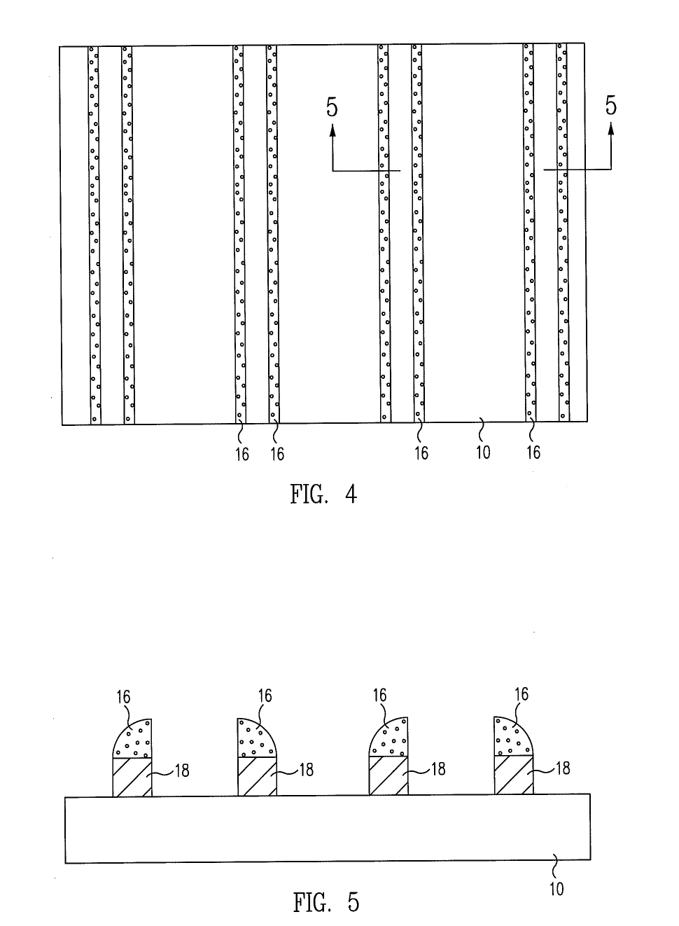

Using the SiₓO_{y} spacers 16 as an etching mask, the substrate structure of FIG. 3 is then subjected to another etching process, e.g., an anisotropic process, to remove substantially all of the target material, i.e., the ferromagnetic material layer 12, from the substrate 10, except for the portions 18 disposed immediately below the SiₓO_{y} spacers. FIG. 4 is a partial top plan view of the resulting structure, and FIG. 5 is a cross-sectional view through the resulting structure, as seen along the lines of the section 5-5 taken in FIG. 4. With reference to FIGS. 4 and 5, the resulting structure comprises the substrate 10 with a plurality of lines 18 of ferromagnetic material, each having a respective SiₓO_{y} spacer 16 disposed on the upper surface thereof.

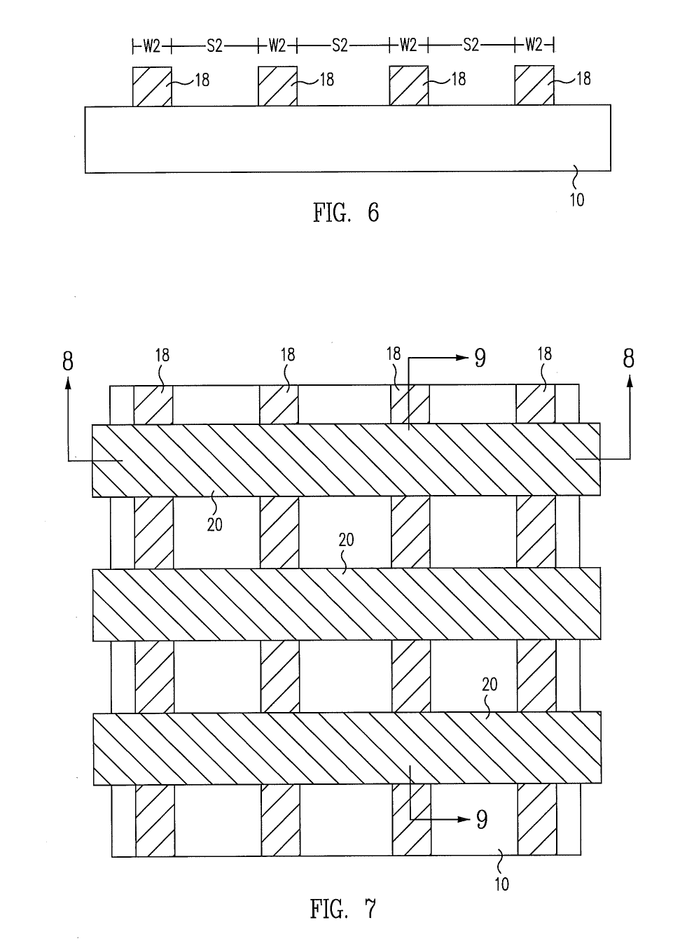

The structure of FIGS. 4 and 5 is then subjected to another etching process to remove the SiₓO_{y} spacers 16 selective to the magnetic material 18, thereby providing the structure illustrated in FIG. 6, comprising a substrate 10 having a plurality of parallel lines of magnetic material 18 disposed thereon, each having a width W2, and being spaced apart from the adjacent lines by a spacing S2. In the particular exemplary embodiment illustrated in FIG. 6, each of the magnetic material lines 18 has a width W2 of about 30 nm and is spaced apart from adjacent lines by a spacing S2 of about 3 times the respective widths of the lines, i.e., at a spacing of about 90 nm. However, these dimensions are only by way of some examples thereof, and the lines 18 may be formed with other widths and/or at other spacings, depending on the particular application at hand.

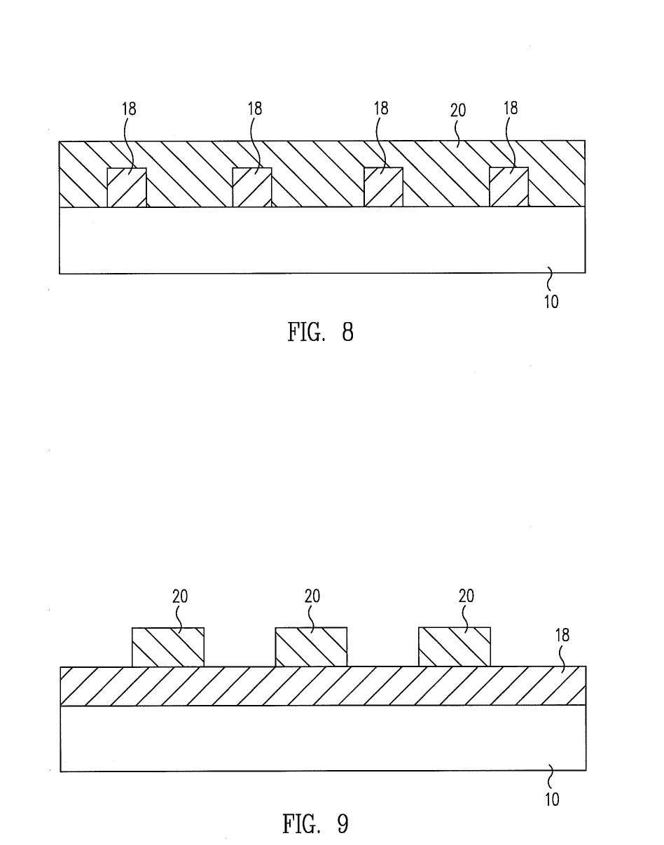

In one possible embodiment and with reference to FIGS. 7-9, the upper surface of the substrate structure of FIG. 6, including the magnetic material lines 18, may then coated with a layer of photoresist, and the photoresist then patterned by exposure to light through an appropriate photo-mask (not illustrated) and developed to form a plurality of parallel bars or lines 20 extending generally perpendicular to the magnetic material lines 18. In the particular exemplary embodiment illustrated, the photoresist lines have respective widths of about 2.5 times the width of the magnetic material lines, i.e., about 75 nm, and are spaced apart from each other at a distance of about 90 nm, but as above, these dimensions can be varied, depending on the particular application. In particular, where the aspect ratio of the dots to be produced on the substrate 10 is 1:2 or 1:2.5 (i.e., the width to length of the dots), the resist lines 20 can be printed with conventional photo tools (i.e., 60 nm or greater). Therefore, the respective widths of the resist lines 20 should be at least 2.5× the width W2 of the magnetic material lines where W2≦30 nm. Moreover, if the final aspect ratio of the dots is to be 1:1 or 1:1.5, and if the width of the magnetic material lines is ≧60 nm, the width of the photo resist lines can still be reliably printed down to as small as ≈60 nm. However, as described in more detail in connection with the alternative embodiment below, if the dots are to have an aspect ratio of ˜1:1 and the width of the magnetic material lines is ≦ about 30 nm, the resist lines cannot be reliably printed with current tools, and as described below, the resist lines are preferably replaced with hard mask spacers 16, as described above, to achieve the desired dot aspect ratio, i.e. 30 nm×30 nm dots.

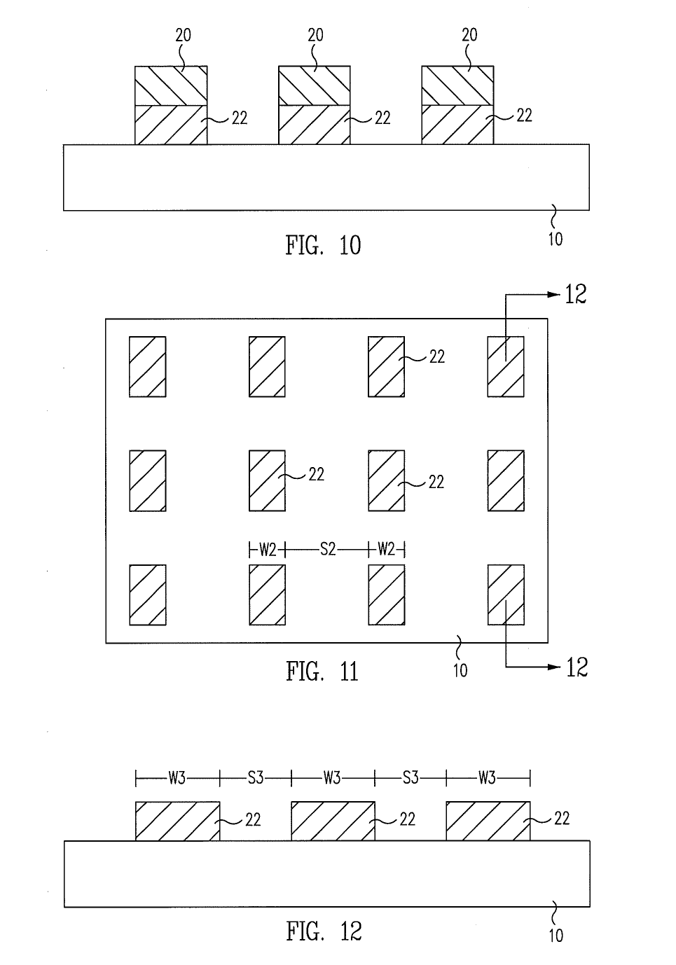

Accordingly, in the exemplary embodiment above, the photoresist lines 20 are formed with a width W3 of about 75 nm, and at a spacing S3 of about 90 nm. The upper surface of the resulting structure of FIGS. 7-9 is then subjected to an etch using the photoresist lines 20 as an etch mask to remove substantially all of the ferromagnetic material layer 12, including the magnetic material lines 18, on the substrate, except for those portions disposed immediately below the photoresist lines. This results in the substrate structure illustrated in the cross-sectional view of FIG. 10, comprising the substrate 10, with a plurality of rectangular dots of magnetic material 22 disposed in the form of a rectangular matrix on the upper surface thereof, each dot having a portion of a photoresist line overlying it. The photoresist lines 20 are then stripped from the structure, resulting in the substrate structure illustrated in the partial top plan view of FIG. 11, and in the cross-sectional view of FIG. 12, as seen along the lines of the section 12-12 taken in FIG. 11.

As illustrated in FIGS. 11 and 12, the structure comprises the substrate 10, with a plurality of ferromagnetic material dots 22 disposed in a rectangular matrix thereon. In the particular embodiment illustrated and described above, each of the dots is rectangular, with an aspect ratio of about W2×W3, and are disposed in the matrix at spacings of about S3 between the respective rows thereof and at about S2 between the columns thereof. That is, in the context of the particular exemplary embodiment described above, each of the dots 22 may have dimensions of about 30 nm×75 nm, and be spaced apart from each other longitudinally and laterally by about 90 nm. Of course, as discussed above, these dimensions are given as examples thereof, and can be varied to suit the particular application at hand.

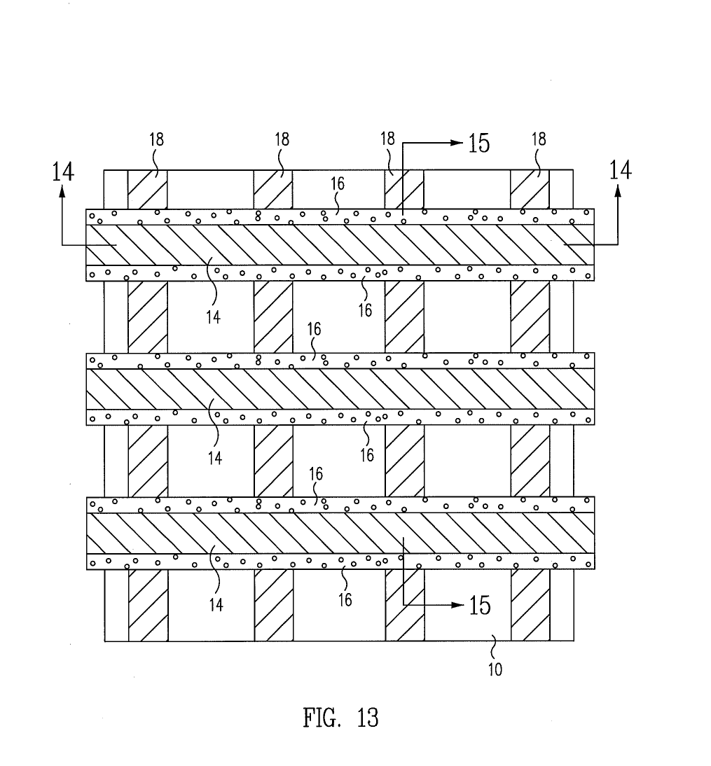

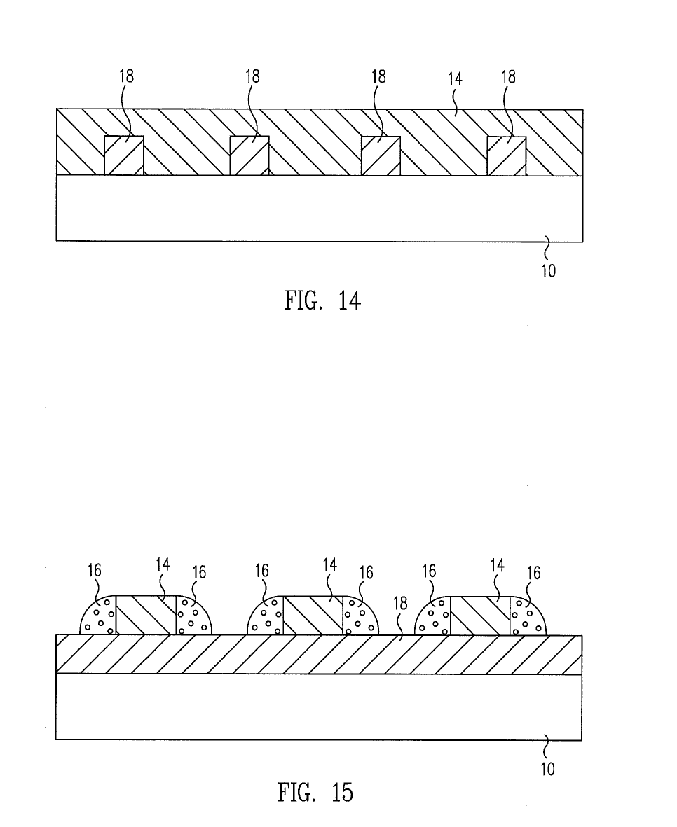

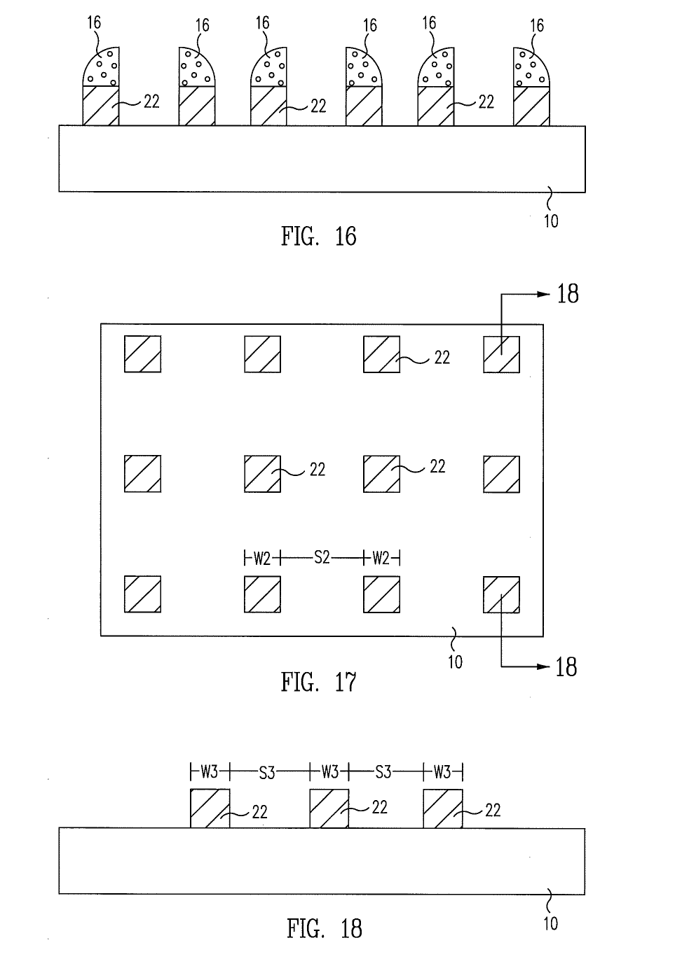

As discussed above, if the dots 22 are to be formed on the substrate 10 with an aspect ratio of ˜1:1 and the width of the magnetic material lines is ≦ about 30 nm, the photoresist lines 20 cannot be reliably printed, i.e., without washout after development, using current tools. In this case, the resist lines 20 above are preferably replaced with hard mask spacers 16, to achieve the desired dot aspect ratio, i.e. 30 nm×30 nm dots, as described in the alternative exemplary embodiment below in connection with FIGS. 13-18.

As illustrated in FIG. 13, the alternative method begins with the substrate structure of FIG. 6, comprising a substrate 10 having a plurality of longitudinal magnetic material lines 18 disposed thereon, each having a width W2 of about 30 nm and disposed at a spacing S2 of about 90 nm from adjacent lines. As illustrated in FIGS. 13-18, and in a manner substantially identical to that described above in connection with FIGS. 1-6, respectively, except that the plurality of parallel, linear SiₓO_{y} spacers 16 that are formed on the substrate 10 extend generally perpendicular to the lines 18 of magnetic material, i.e., transversely. As in the above embodiment, the SiₓO_{y} spacers 16 have a width W2 of about 30 nm, and are disposed at a spacing S3 of about 90 nm.

As illustrated in FIGS. 17 and 18, after the final etch and removal of the SiₓO_{y} spacers 16, the resulting structure comprises the substrate 10, with a plurality of ferromagnetic material dots 22 disposed in a rectangular matrix thereon. In the particular embodiment illustrated and described above, each of the dots is square, with an aspect ratio of about W2×W3, and are disposed in the matrix at spacings of about S3 between the respective rows thereof and at about S2 between the columns thereof. That is, in the context of the particular exemplary embodiment described above, each of the dots 22 may have dimensions of about 30 nm×30 nm, and be spaced apart from each other longitudinally and laterally by about S2=S3=90 nm.

As may be seen from the foregoing description, rather than attempting to print and etch the very small isolated dots 22 of a target material on the substrate 10 in a single print and etch step, the novel method instead proceeds by the successive formation of orthogonally intersecting linear patterns on the substrate 10, including the formation and use of “hard” etch masks and selective etching techniques, so as to enable very small geometry (<65 nm) isolated dots of a target material to be formed on a semiconductor substrate reliably and using conventional 193 nm wavelength light for photoresist exposure, thereby overcoming the problem of isolated small pattern washout during development of conventional photolithographic processes and enabling the production of high reliability, low cost memory products.

As those of skill in this art will appreciate, many modifications, substitutions and variations can be made in the photolithography methods of the present disclosure without departing from its spirit and scope. For example, although the exemplary methods have been described in the context of the formation of dots of a magnetic or phase change material on a substrate, it should be understood the methods of the disclosure can be used to form dots of many other types of target materials on a substrate.

Additionally, as the linear SiₓN_{y} and SiₓO_{y} etch masks and spacers described above are utilized as “hard” etch masks, their respective roles can easily be interchanged in the method by the appropriate choice of the respective selective etching techniques used in conjunction therewith. That is, the hard etch mask lines 14 of FIGS. 1 and 2 can comprise SiₓO_{y} rather than SiₓN_{y}, and the hard etch mask spacers 16 of FIGS. 2-5 can comprise SiₓN_{y} rather than SiₓO_{y}, provided that the respective selective etch processes used in conjunction therewith are correspondingly reversed.

In light of the foregoing, the scope of the present disclosure should not be limited to that of the particular embodiments illustrated and described herein, as they are only by way of some examples thereof, but instead, should be fully commensurate with that of the claims appended hereafter and their functional equivalents.

What is claimed is:

1. A method for forming very small isolated dots of a target material on a substrate, the method comprising:
providing a substrate having a layer of the target material disposed on a surface thereof;
etching the layer of target material so as to form a plurality of lines of the target material on the surface of the substrate; and,
etching the lines of the target material so as to form a rectangular matrix of substantially similar isolated dots of the target material on the surface of the substrate.

2. The method of claim 1, wherein the etching of the layer of target material comprises:
forming a plurality of linear spacers of a hard etch masking material on a surface of the layer of target material;
selectively etching the layer of target material using the linear spacers as an etch mask so as to remove all of the target material from the substrate except for that underlying the spacers; and,
removing the linear spacers from the substrate.

3. The method of claim 1, wherein the etching of the lines of target material comprises:
forming a plurality of lines of a photoresist material on the surface of the substrate, the photoresist lines extending in a direction generally perpendicular to the lines of the target material;
selectively etching the lines of target material using the photoresist lines as an etch mask so as to remove all of the target material from the substrate except for that underlying the photoresist lines; and,
removing the photoresist lines from the substrate.

4. The method of claim 2, wherein the forming of the linear spacers comprises:
forming a plurality of lines of a first hard etch masking material on the surface of the target material;
forming a layer of a second hard etch masking material over the surface of the substrate;
selectively etching the layer of the second hard etch masking material so as remove all of the second hard etch masking material except for a plurality of rounded linear spacers respectively disposed on opposite sides of the lines of the first hard etch masking material; and,
removing the lines of the first hard etch masking material from the substrate.

5. The method of claim 4, wherein the forming of the lines of the first hard etch masking material comprises:
forming a layer of the first hard etch masking material on the surface of the target material;
forming a plurality of lines of a photoresist material over a surface of the layer of the first hard etch masking material;
selectively etching the layer of first hard etch masking material using the photoresist lines as an etch mask so as to remove substantially all of the first hard etch masking material from the substrate except for that underlying the photoresist lines; and,
removing the photoresist lines from the substrate.

6. The method of claim 1, wherein the etching of the lines of target material comprises:
forming a plurality of linear spacers of a hard etch masking material on the surface of the substrate, the linear spacers extending in a direction generally perpendicular to the lines of the target material;
selectively etching the lines of target material using the linear spacers as an etch mask so as to remove substantially all of the target material from the substrate except for that underlying the linear spacers; and,
removing the linear spacers from the substrate.

7. The method of claim 6, wherein the forming of the linear spacers comprises:
forming a plurality of lines of a first hard etch masking material on the surface of the substrate;
forming a layer of a second hard etch masking material over the surface of the substrate;
selectively etching the layer of the second hard etch masking material so as remove substantially all of the second hard etch masking material except for a plurality of rounded linear spacers respectively disposed on opposite sides of the lines of the first hard etch masking material; and,
removing the lines of the first hard etch masking material from the substrate.

8. The method of claim 7, wherein the forming of the lines of the first hard etch masking material comprises:
forming a layer of the first hard etch masking material on the surface of the target material;
forming a plurality of lines of a photoresist material over a surface of the layer of the first hard etch masking material;
selectively etching the layer of first hard etch masking material using the photoresist lines as an etch mask so as to remove substantially all of the first hard etch masking material from the substrate except for that underlying the photoresist lines; and,
removing the photoresist lines from the substrate.

9. The method of claim 1, wherein the substrate comprises a semiconductor material.

10. The method of claim 1, wherein the target material comprises a ferromagnetic material.

11. The method of claim 1, wherein each dot has a length and a width, at least one of which is less than 65 nm.

12. The method of claim 11, wherein:
the rectangular matrix of dots comprises a plurality of rows and columns,
the rows are separated from each other at a spacing of about three times the width of a dot; and,
the rows are separated from each other at a spacing of about three times the width of a dot.

13. The method of claim 4, wherein:
the first hard etch masking material comprises silicon nitride (SiₓN_{y}); and,
the second hard etch masking material comprises silicon oxide (SiₓO_{y}).

14. The method of claim 4, wherein:
the first hard etch masking material comprises silicon oxide (SiₓO_{y}); and,
the second hard etch masking material comprises silicon nitride (SiₓN_{y}).

15. The method of claim 8, wherein:
the first hard etch masking material comprises silicon nitride (SiₓN_{y}); and,
the second hard etch masking material comprises silicon oxide (SiₓO_{y}).

16. The method of claim 8, wherein:
the first hard etch masking material comprises silicon oxide (SiₓO_{y}); and,
the second hard etch masking material comprises silicon nitride (SiₓN_{y}).

17. A Magnetoresistive Random Access Memory (MRAM) manufactured at least in part by the method of claim 1.

18. A method for forming very small isolated dots of a target material on a substrate, the method comprising:
providing a substrate having a layer of the target material disposed on a surface thereof;
forming a layer of a first hard etch masking material on a surface of the target material;
forming a first layer of a photoresist material over a surface of the first hard etch material layer;
exposing the first photoresist layer to light through a mask to define a plurality of lines therein, the lines extending in a first direction;
developing the first photoresist layer to form a plurality of first photoresist lines on the surface of the first hard etch material layer;
selectively etching the layer of first hard etch masking material using the first photoresist lines as an etch mask so as to remove all of the first hard etch masking material from the substrate except for that underlying the photoresist lines and defining lines of the first hard etch masking material on the substrate;
removing the photoresist lines from the substrate;
forming a layer of a second hard etch masking material over the surface of the substrate;
selectively etching the layer of the second hard etch masking material so as remove all of the second hard etch masking material except for a plurality of first rounded linear spacers respectively disposed on opposite sides of the lines of the first hard etch masking material and extending in the first direction;
removing the lines of the first hard etch masking material from the substrate;
selectively etching the layer of target material using the first linear spacers as an etch mask so as to form a plurality of lines of the target material underlying the first spacers and extending in the first direction on the substrate; and,
removing the first linear spacers from the substrate.

19. The method of claim 18, further comprising:
forming a second layer of a photoresist material over the surface of the substrate;
exposing the second layer of photoresist material to light through a mask to define a plurality of second lines therein, the second lines extending in a second direction generally perpendicular to the first direction;
developing the second photoresist layer to form a plurality second photoresist lines on the surface of the substrate;
selectively etching the lines of target material using the second photoresist lines as an etch mask so as to form a rectangular matrix of substantially similar isolated dots of the target material underlying the second photoresist lines on the surface of the substrate; and,
removing the second photoresist lines from the substrate.

20. The method of claim 18, further comprising:
forming a layer of a third hard etch masking material on a surface of the target material;
forming a second layer of a photoresist material over a surface of the first hard etch material layer;
exposing the second photoresist layer to light through a mask to define a plurality of lines therein, the lines extending in a second direction generally perpendicular to the first direction;
developing the second photoresist layer to form a plurality of second photoresist lines on the surface of the first hard etch material layer;
selectively etching the layer of the third hard etch masking material using the second photoresist lines as an etch mask so as to remove all of the third hard etch masking material from the substrate except for that underlying the second photoresist lines and defining lines of the third hard etch mask on the substrate;
removing the second photoresist lines from the substrate;
forming a layer of a fourth hard etch masking material over the surface of the substrate;
selectively etching the layer of the fourth hard etch masking material so as remove all of the fourth hard etch masking material except for a plurality of second rounded linear spacers respectively disposed on opposite sides of the lines of the third hard etch masking material, the second linear spacers extending in the second direction;
removing the lines of the third hard etch masking material from the substrate;
selectively etching the lines of target material using the second linear spacers as an etch mask so as to form a rectangular matrix of substantially similar isolated dots of the target material underlying the second linear spacers on the surface of the substrate; and,
removing the second linear spacers from the substrate.

21. The method of claim 18, wherein the substrate comprises a semiconductor.

22. The method of claim 18, wherein each dot has a length and a width, at least one of which is about 30 nm.

23. The method of claim 18, wherein the surface of the substrate comprises an active surface having at lest one semiconductor component formed therein.

24. The method of claim 23, wherein the at least one semiconductor component comprises a complementary metal oxide semiconductor (CMOS) transistor.

25. A Magnetoresistive Random Access Memory (MRAM) manufactured at least in part by the method of claim 18.
